(19) United States
(12) Patent Application Publication
(10) Pub. No.: US 2016/0324039 A1
(43) Pub. Date: Nov. 3, 2016

(54) Cooling Case for Electronic Device, Electronic Device, and Construction Machine

(71) Applicant: KOMATSU LTD., Minato-ku, Tokyo (JP)

(72) Inventors: Akihiko Souda, Fujisawa-shi, Kanagawa (JP); Junichirou Tsuchiya, Odawara-shi, Kanagawa (JP)

(21) Appl. No.: 14/786,762

(22) PCT Filed: Apr. 28, 2015
(86) PCT No.: PCT/JP2015/062799

§ 371 Date: Oct. 23, 2015

(51) Int. Cl. H05K 7/20; E02F 9/08

(52) U.S. Cl. CPC H05K 7/20927; E02F 9/0866

(57) ABSTRACT

A cooling case for an electronic device includes: a floor portion defining a cooling channel where a coolant flows; a first arrangement section, in which a first electronic component is disposed, defined in one of top and bottom surfaces of the floor portion; a second arrangement section, in which a second electronic component is disposed, defined in the other of the top and bottom surfaces; and a third arrangement section being in communication with the first and second arrangement sections through an opening of the floor portion. A smoothing capacitor unit is disposed in the third arrangement section to face both the top and bottom surfaces of the floor portion and includes first power storage portion for a circuit of the first electronic component and second power storage portion for a circuit of the second electronic component, which are integral with each other.

### TECHNICAL FIELD

The present invention relates to a cooling case for an electronic device, an electronic device, and a construction machine.

### BACKGROUND ART

A working machine in a form of a hybrid hydraulic excavator that drives working equipment such as a boom, arm and bucket using hydraulic oil from a hydraulic pump driven by an engine, and rotates an upper revolving body with an electric rotating motor has been recently known (see, for instance, Patent Literature 1). FIG. 6 shows an arrangement of a hybrid device used in the hydraulic excavator of Patent Literature 1.

An engine 3 of the hydraulic excavator 1 shown in FIG. 6 is mounted in an engine compartment 2A disposed on a rear side of an upper revolving body 2 in a manner that an axial direction of a crank shaft (not shown) is parallel to a vehicle width direction (i.e. horizontal direction orthogonal to a front-rear direction of the vehicle). In addition, a cooling fan 4 for sucking cooling air from an outside into the engine compartment 2A, an engine radiator 5, a hybrid radiator 6 and a plurality of hybrid units that are to be cooled by the sucked cooling air are disposed on a side of the engine 3 in the vehicle width direction sequentially toward the outside.

The hybrid units include a power-generating motor (not shown) disposed on the other side of the engine 3 and driven by the engine 3, a capacitor 7 for storing electric power generated by the power-generating motor, an inverter 8 for controlling storage/supply of the electric power in/from the capacitor 7, and an electric rotating motor 9 driven by the electric power from the capacitor 7. The capacitor 7 and the inverter 8 are provided in a unit together with a terminal box and are disposed at a position accessible through an openable/closable side cover 2B.

The capacitor 7, the inverter 8 and the electric rotating motor 9 are cooled by a dedicated cooling-water circuit including the hybrid radiator 6. The cooling water cooled by the hybrid radiator 6 is initially delivered through a pipe W1 to the capacitor 7 using the cooling water pump P. The cooling water having cooled the capacitor 7 is delivered through a pipe W2 to the inverter 8 disposed on an upper side of the capacitor 7. The cooling water having cooled the inverter 8 is delivered through a pipe W3 to the electric rotating motor 9. The cooling water having cooled the electric rotating motor 9 is delivered through a pipe W4 to be returned to the hybrid radiator 6.

A cooling case for an electronic device, especially an inverter, is known (see, for instance, Patent Literature 2). The cooling case includes: a case chassis having upper and lower openings; a cooling floor defining therein a cooling circuit through which a coolant is circulated; a recessed arrangement section delimited by a side wall upwardly opening in a space surrounded by the case chassis.

In the cooling case, switching module(s) of a driver circuit for a generator motor is disposed on an upper surface of the cooling floor, a smoothing capacitor for smoothing a pulsating current generated by a switching operation on the driver circuit is disposed on a lower surface of the cooling floor, and a step-up transformer is disposed in the arrangement section to be in contact with the side wall.

In the inverter, the switching module(s), the smoothing capacitor and the transformer are heated to a high temperature. However, the above arrangement allows for efficient cooling of the switching module(s) through the upper surface of the cooling floor, the capacitor through the lower surface and the transformer through the side wall continuous with the cooling floor.

### CITATION LIST

### Patent Literature(s)

Patent Literature 1 JP-A-2012-112102

Patent Literature 2 JP-A-2008-218713

### SUMMARY OF THE INVENTION

### Problem(s) to be Solved by the Invention

In the typical cooling case disclosed in Patent Literature 2, the switching module(s) and the smoothing capacitor are respectively disposed on the upper and lower surfaces of the cooling floor to be efficiently cooled. However, in the case of the necessity of, for instance, an additional switching module(s) for a step-up control of the transformer and an additional smoothing capacitor for suppressing a pulsating current caused by the additional switching module(s), the switching module(s) and the capacitor for a drive control of the generator motor have to be juxtaposed to each other on one of the upper and lower surfaces of the cooling floor, while the switching module(s) and the capacitor for the step-up control have to be juxtaposed to each other on the other surface due to distance requirements between the switching modules and the capacitors. When the capacitors are disposed on the upper and lower surfaces, an additional component for electric power transmission is necessary for transmission/receipt of electric power between electronic components on the upper and lower surfaces for a systematic reason. The typical cooling case thus entails a problem that, for instance, an assembly process of the inverter requires time and efforts due to an increase in the number of components disposed on the upper and lower surfaces of the cooling floor and a complicated arrangement of the components.

An object of the invention is to provide a cooling case for an electronic device, and an electronic device and a construction machine provided therewith, the cooling case being configured to improve a work efficiency in, for instance, an assembly process and satisfy distance requirements between an electronic component and a capacitor.

### Means for Solving the Problem(s)

According to a first aspect of the invention, a cooling case for an electronic device includes: a floor portion defining therein a cooling channel through which a coolant flows; a first arrangement section where a first electronic component is disposed, the first arrangement section being defined in one of top and bottom surfaces of the floor portion; a second arrangement section where a second electronic component is disposed, the second arrangement section being defined in the other of the top and bottom surfaces of the floor portion; and a third arrangement section being in communication with the first arrangement section and the second arrangement section through an opening provided to the floor portion, in which a smoothing capacitor unit is disposed in the third arrangement section to face both of the top and bottom surfaces of the floor portion, the smoothing capacitor including a first power storage portion for a circuit provided to the first electronic component and a second power storage portion for a circuit provided to the second electronic component, the first power storage portion and the second power storage portion being integral with each other.

In the above aspect, the cooing case defines the third arrangement section that is in communication with the first and second arrangement sections through the opening, and the smoothing capacitor is disposed in the opening. The smoothing capacitor may thus be in the form of a single component including the integral first and second power storage portions. Therefore, the number of components can be reduced and, consequently, a work efficiency in, for instance, an assembly process can be improved. Further, since the smoothing capacitor is disposed to face both of the top and bottom surfaces of the floor portion, for instance, switching modules of the first and second electronic components can be disposed close to the smoothing capacitor to be connected thereto. Distance requirements between the electronic components and the smoothing capacitor can thus be satisfied.

In the above aspect, it is preferable that the floor portion include a first planar portion of the one of the top and bottom surfaces of the floor portion and a second planar portion of the other of the top and bottom surfaces of the floor portion, the cooling channel be defined between the first planar portion and the second planar portion, and at least one of a first fin and a second fin be provided in the cooling channel, the first fin projecting from the first planar portion toward the second planar portion, the second fin projecting from the second planar portion toward the first planar portion.

In the above aspect, it is preferable that the floor portion include a first planar portion of the one of the top and bottom surfaces of the floor portion and a second planar portion of the other of the top and bottom surfaces of the floor portion, the cooling channel be defined between the first planar portion and the second planar portion, and at least one of the first planar portion and the second planar portion be in a form of a cover plate fixed to the other of the first planar portion and the second planar portion.

In the above aspect, it is preferable that the cooling case be in a substantially rectangular shape having long sides and short sides in a plan view, the opening be disposed beside one of the long sides, and the cooling channel be disposed beside the other one of the long sides.

In the above aspect, it is preferable that a plurality of terminals be provided to an exterior of the smoothing capacitor unit, and a DC bus board be embedded in the smoothing capacitor unit so that the terminals are electrically conductive to one another through the DC bus board.

According to a second aspect of the invention, an electronic device includes the above cooling case.

According to a third aspect of the invention, a construction machine includes the above electronic device.

### BRIEF DESCRIPTION OF DRAWING(S)

FIG. 1 is an exploded perspective view showing an electronic device including a cooling case according to an exemplary embodiment of the invention as viewed from below a bottom surface thereof.

FIG. 2 is a plan view showing a relevant part of the electronic device.

FIG. 3 is a bottom view showing the relevant part of the electronic device.

FIG. 4 is a cross section showing the electronic device as viewed in a direction indicated by arrows IV-IV in FIG. 2.

FIG. 5 is a schematic view showing a modification of the invention.

FIG. 6 is a perspective view illustrating a related art.

### DESCRIPTION OF EMBODIMENT(S)

### Description of Overall Arrangement of Inverter

Exemplary embodiment(s) of the invention will be described below with reference to the attached drawings.

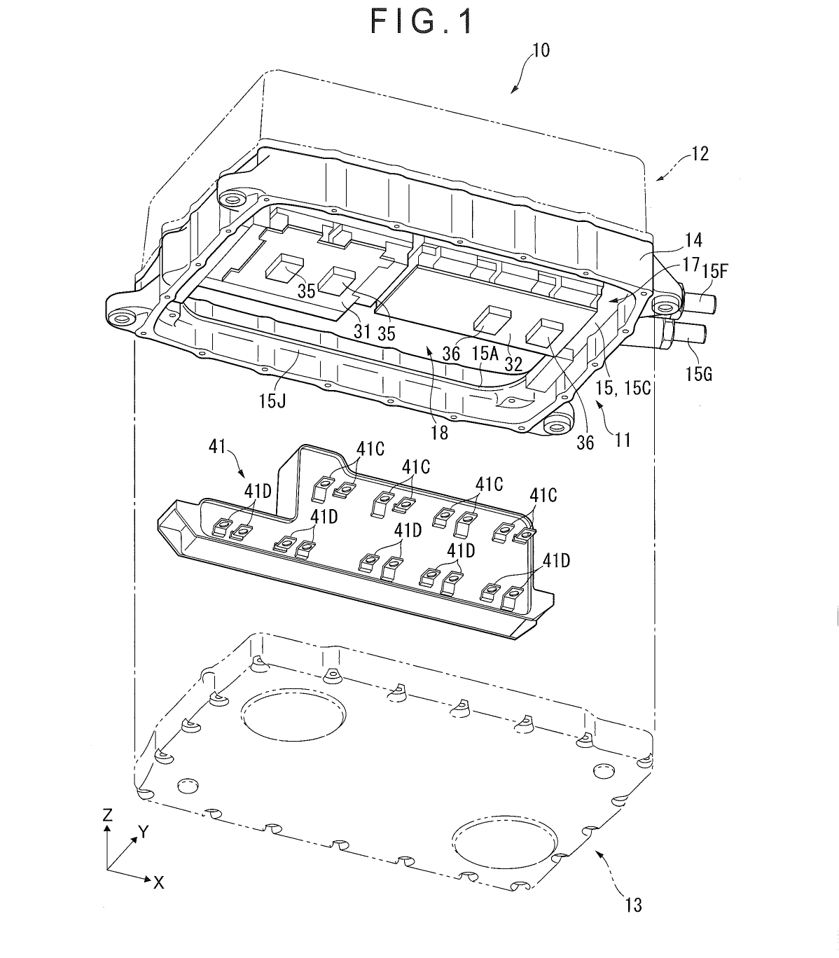

FIG. 1 is an exploded perspective view showing an inverter (electronic device) including a cooling case (hereinafter, referred to as “case”) according to an exemplary embodiment as viewed from below a bottom surface thereof.

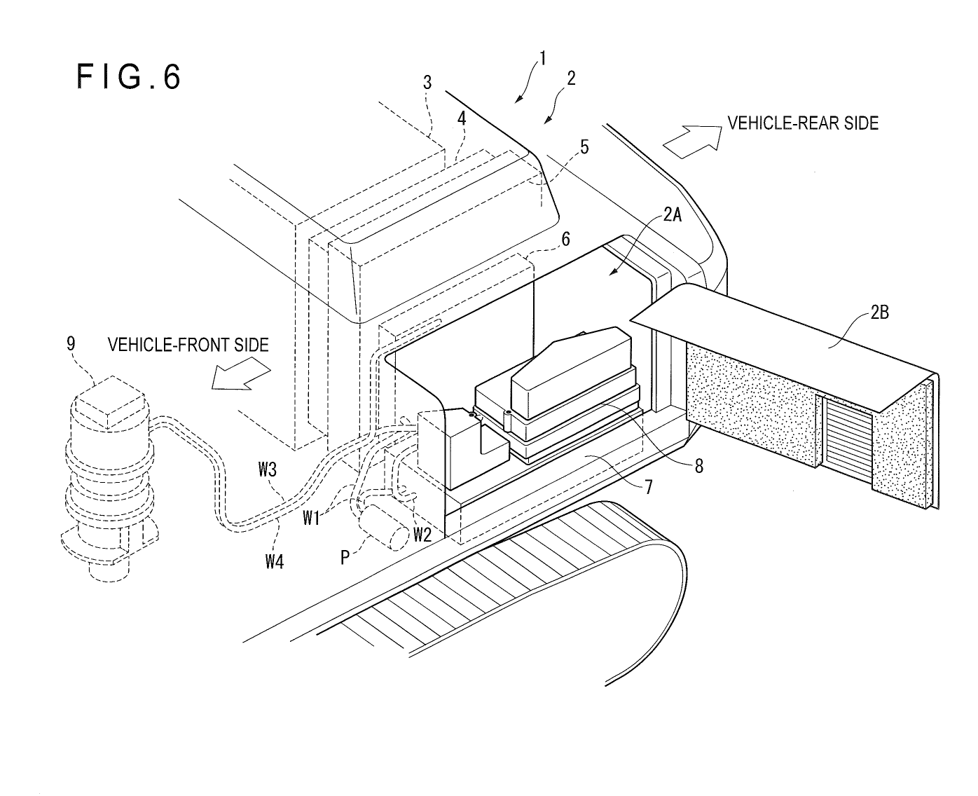

A function and usage of an inverter 10 shown in FIG. 1 are the same as those of the above-described inverter 8 described with reference to FIG. 6. The inverter 10 is mounted in a hybrid hydraulic excavator 1 (construction machine). The inverter 10 includes: a case 11 shown by solid lines in FIG. 1; an aluminum die-cast upper cover 12 that covers an upper side of the case 11; an aluminum die-cast lower cover 13 that covers a lower side of the case 11; and a variety of electric/electronic components attached to the case 11 and the covers 12, 13.

### Description of Case

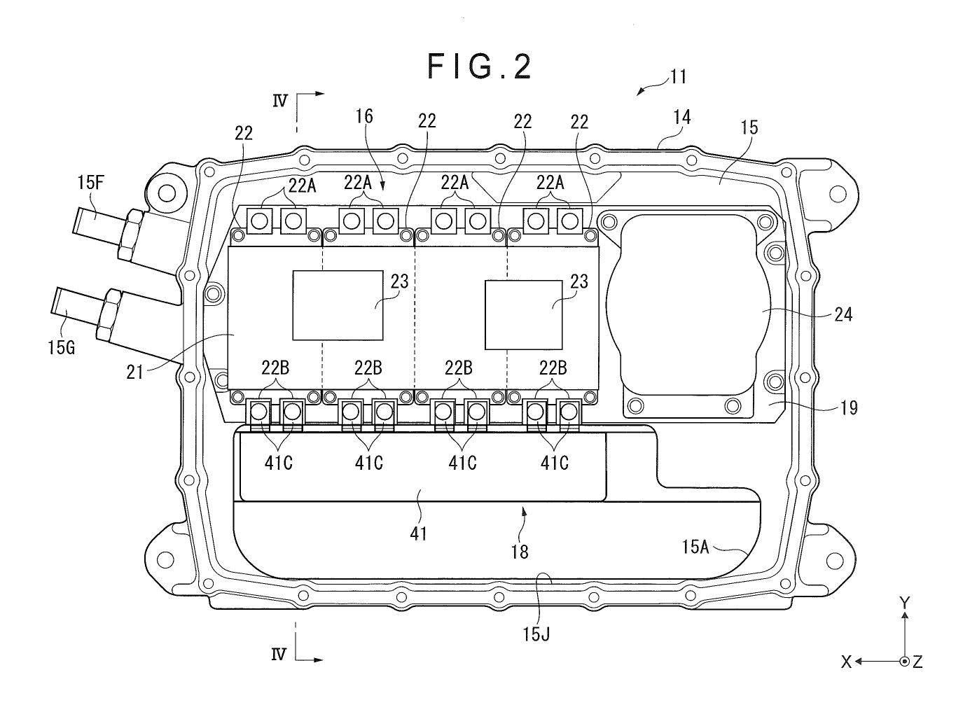

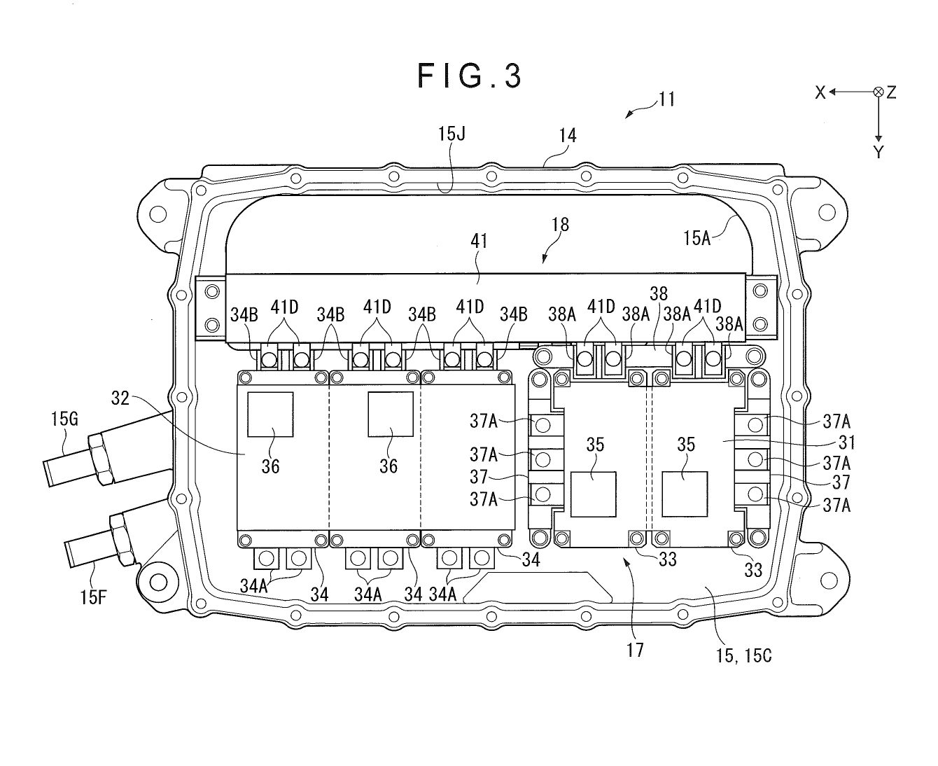

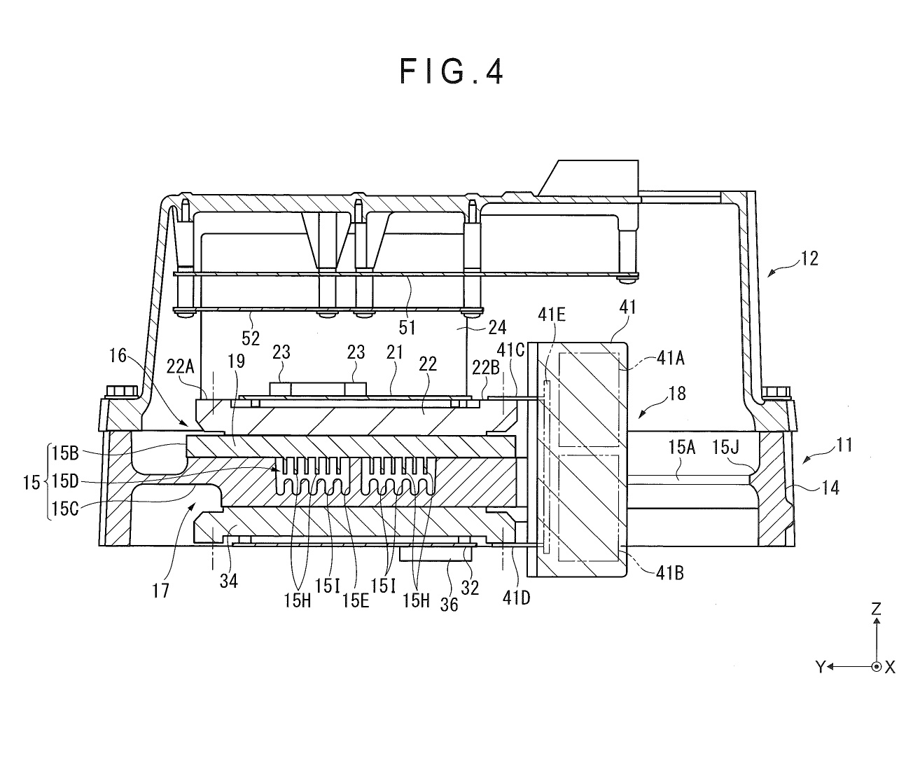

FIG. 2 is a plan view showing a relevant part of the inverter 10, FIG. 3 is a bottom view showing the relevant part, and FIG. 4 is a cross section showing the relevant part as viewed in a direction indicated by arrows IV-IV in FIG. 2. Incidentally, the lower cover 13 is not shown in FIG. 4.

As shown in FIGS. 1 to 4, the case 11, which is in a substantially rectangular shape having long sides and short sides in a plan view, includes: a chassis 14 that is similarly in a substantially rectangular shape in a plan view; and a floor portion 15 that vertically divides the chassis 14. In the case 11, a first arrangement section 16 is defined on one of top and bottom surfaces of the floor portion 15 (an upper surface of the floor portion 15), a second arrangement section 17 is defined on the other of the top and bottom surfaces of the floor portion 15 (a lower surface of the floor portion 15), and a third arrangement section 18 is defined to be in communication with the first arrangement section 16 and the second arrangement section 17 through an opening 15A provided to the floor portion 15.

The floor portion 15 includes a first planar portion 15B of the upper surface, a second planar portion 15C of the lower surface; and a cooling channel 15D provided between the first planar portion 15B and the second planar portion 15C. The first planar portion 15B is provided by a plate-shaped cover plate 19 detachably fixed to the second planar portion 15C with a bolt or the like. The second planar portion 15C includes a groove-shaped portion 15E opened toward the first planar portion 15B. The cooling channel 15D is a circulation space for a coolant defined by the groove-shaped portion 15E and the cover plate 19 covering the groove-shaped portion 15E. The cooling channel 15D, which is in a U-shape channel including linear forward route and return route extending in a long-side direction of the case 1 in a plan view (the shape of the cooling channel 15D is not described in detail herein), includes an inlet portion 15F and an outlet portion 15G for a cooling water respectively defined at first and second ends thereof. The inlet portion 15F and the outlet portion 15G are juxtaposed to each other at a short-side surface of the case 11.

The chassis 14 and the second planar portion 15C of the floor portion 15 are integrally formed by aluminum die-casting, and the cover plate 19 is an extruded article. In the cooling channel 15D, a plurality of first fins 15H project from the first planar portion 15B toward the second planar portion 15C, and a plurality of second fins 15I project from the second planar portion 15C toward the first planar portion 15B. The cover plate 19 is manufactured by forming an extruded article having a surface substantially entirely provided with fins and removing the fins except ones (the first fins 15H) corresponding to a linear portion of the cooling channel 15D.

The opening 15A is in a substantially L-shape in a plan view and the floor portion 15 is in a rectangular shape in a plan view. The opening 15A is opened in the floor portion 15 over an area of the entire longitudinal length thereof and approximately one third of a lateral length thereof. Further, the opening 15A is opened at a position beside a long side 15J along a longitudinal direction of the floor portion 15. The cooling channel 15D is thus provided at a position where the opening 15A is not provided. Specifically, the cooling channel 15D is provided beside the other one of the long sides.

### Description of First Arrangement Section

In the first arrangement section 16, a plurality of booster switching modules 22 (first electronic component) are arranged side by side on the first planar portion 15B. The booster switching modules 22 each include an inner booster switching element (heat source) provided by an insulated gate bipolar transistor (not shown). A gate substrate 21 is disposed over the booster switching modules 22. The gate substrate 21 is electrically conductive to the inner switching elements through a connecting unit (not shown), and components such as a power transformer 23 are mounted on the gate substrate 21.

The booster switching modules 22 are firmly in contact with an upper surface of the first planar portion 15B, and heat generated by the inner switching elements is radiated through the first planar portion 15B to the cooling water flowing through the cooling channel 15D. The switching elements are thus cooled. Further, heat from a step-up transformer 24 (heat source) disposed in the first arrangement section 16 is similarly radiated.

The booster switching modules 22 each have opposite first and second side surfaces respectively provided with a pair of projecting terminal blocks 22A and a pair of projecting terminal blocks 22B. The terminal blocks 22A, 22B are electrically conductive to the inner switching elements. Ones of the terminal blocks 22A distanced from the third arrangement section 18 are connected to base ends of a pair of cables (not shown) electrically conductive to a primary side of the gate substrate 21. Distal ends of the cables are connected to a primary side of the step-up transformer 24. A secondary side of the step-up transformer 24 is connected to base ends of another pair of cables (not shown), and distal ends of these cables are connected to different ones of the terminal blocks 22A so that the secondary side of the step-up transformer 24 is electrically conductive to the switching elements at a secondary side through the terminal blocks 22A.

### Description of Second Arrangement Section

In the second arrangement section 17, a pair of generator motor switching modules 33 (second electronic component) and a plurality of swing motor switching modules 34 (second electronic component) are arranged side by side on the second planar portion 15C. The generator motor switching modules 33 each include an inner generator motor switching element (heat source) provided by an insulated gate bipolar transistor (not shown), and the swing motor switching modules 34 each include an inner swing motor switching element (heat source) provided by an insulated gate bipolar transistor (not shown). Gate substrates 31, 32 are respectively disposed over the switching modules 33, 34. The gate substrates 31, 32 are electrically conductive to the inner switching elements through a connecting unit (not shown), and components such as power transformers 35, 36 are respectively mounted on the gate substrates 31, 32. Heat generated by the inner switching elements is radiated through the second planar portion 15C to the cooling water flowing through the cooling channel 15D. The switching elements are thus cooled.

Further, in the second arrangement section 17, support members 37, 38 are provided around the generator motor switching modules 33 arranged side by side except a side distanced from the third arrangement section 18. Specifically, the support members 37 (a pair of them) are disposed at opposite sides across the generator motor switching modules 33 to be distanced from each other, and the support member 38 is disposed near the third arrangement section 18.

The support members 37 each include three terminal blocks 37A. The terminal blocks 37A are electrically connected to the inner switching elements of the generator motor switching modules 33 through a conducting unit (not shown). The support member 38 includes four terminal blocks 38A. The terminal blocks 38A are electrically connected to the inner switching elements of the generator motor switching modules 33 through a conducting unit (also not shown).

The terminal blocks 37A of each of the support members 37 are individually connected to distal ends of three cables (not shown). The six cables in total have base ends connected to the terminal block in the terminal box provided to the upper cover 12, and the terminal block is further connected to a generator motor (not shown) driven by the engine 3 (see FIG. 6) through six power cables. The power cables are used to transmit electric power generated by the generator motor to the inverter 10.

The swing motor switching modules 34 each have opposite first and second side surfaces respectively provided with a pair of terminal blocks 34A and a pair of terminal blocks 34B. The terminal blocks 34A, 34B are electrically connected to the inner switching elements of the swing motor switching modules 34 through a conducting unit (not shown). The terminal blocks 34A distanced from the third arrangement section 18 are connected to base ends of three cables (not shown). A base end of each of the cables is connected to a terminal block in a terminal box provided to the upper cover 12, and the terminal block is further connected to the electric rotating motor 9 (see FIG. 6) through three power cables. The power cables are provided to transmit electric power stored in the capacitor 7 to the electric rotating motor 9 through the inverter 10.

### Description of Third Arrangement Section

A smoothing capacitor unit 41 is disposed in the third arrangement section 18 to face both surfaces of the floor portion 15. The smoothing capacitor unit 41 includes a first power storage portion 41A for the booster switching modules 22 and a second power storage portion 41B for the generator motor switching modules 33 and the swing motor switching modules 34, the first power storage portion 41A and the second power storage portion 41B being integral with each other. The smoothing capacitor unit 41, which may be a film capacitor, is in a substantially L-shape in a side view as shown in FIG. 1. Specifically, an upper portion of the smoothing capacitor unit 41A is short in length along a longitudinal direction of the opening 15A, while a lower portion of the smoothing capacitor unit 41A is long.

A length of the upper portion of the smoothing capacitor unit 41 is substantially the same as that of a side of the gate substrate 21 closely opposite with the smoothing capacitor unit 41, and a length of the lower portion is substantially the same as the sum of lengths of the respective sides of the gate substrates 31, 32 opposite with the smoothing capacitor unit 41. As shown in FIG. 4, in the smoothing capacitor unit 41, the first power storage portion 41A is provided in the upper portion corresponding to the first arrangement section 16, while the second power storage portion 41B is provided in the lower portion corresponding to the second arrangement section 17.

The upper portion of the smoothing capacitor unit 41 is inserted into the opening 15A from below. In the opening 15A, the smoothing capacitor unit 41 is disposed beside the first and second arrangement sections 16, 17 in the opening 15A and fixed to the lower surface of the floor portion 15 at longitudinal sides thereof as shown in FIGS. 2 and 3. When the smoothing capacitor unit 41 is disposed in the third arrangement section 18, a thickness of the smoothing capacitor unit 41 accounts for approximately half of an opening area of the opening 15A. The rest of the opening area of the opening 15A not occupied by the smoothing capacitor unit 41 is used as a space where the cables are inserted to be connected to the terminal blocks 34A, 37A and an attachment member or the like for attaching the cables is provided.

It should be noted that first ends of the cables are connected to the terminal blocks 34A, 37A distanced from the opening 15A in the second arrangement section 17, while second ends are inserted through the opening 15A to be connected to the terminal block in the terminal box disposed above the opening 15A. The cables are thus bent at 90 degrees to be arranged in the inverter 10.

An upper portion of a side surface of the smoothing capacitor unit 41 facing the first and second arrangement sections 16, 17 is provided with a plurality of projecting terminals 41C arranged along the longitudinal direction, and a lower portion is provided with a plurality of projecting terminals 41D arranged along the longitudinal direction. The terminals 41C individually correspond to the terminal blocks 22B of the plurality of booster switching modules 22 in the first arrangement section 16 as shown in FIG. 2, and are screwed to the terminal blocks 22B. Similarly, the terminals 41D individually correspond to the terminal blocks 38A of the support member 38 and the terminal blocks 34B of the plurality of swing motor switching modules 34 in the second arrangement section 17 as shown in FIG. 3, and are screwed to the terminal blocks 34B, 38A. Since the smoothing capacitor unit 41 is disposed beside the first and second arrangement sections 16, 17 in the third arrangement section 18, the terminals 41C, 41D may be shortened and heat from the smoothing capacitor unit 41 (heat source) is easily transmitted to the cooling channel 15D.

Further, a direct current (DC) bus board 41E is embedded in the smoothing capacitor unit 41 at a position between the terminals 41C, 41D and the first and second power storage portions 41A, 41B, and predetermined ones of the terminals 41C, 41D are electrically connected to the first and second power storage portions 41A, 41B through a circuit formed on the DC bus board 41E. The switching modules 22, 33, 34 can thus be reliably disposed close to the smoothing capacitor unit 41 to satisfy distance requirements therebetween.

Further, in the exemplary embodiment, the DC bus board 41E functions as a DC bus, so that specific ones of the terminals 41C, 41D are mutually electrically conductive through a DC line using the circuit of the DC bus board 41E. Consequently, when the specific ones of the terminals 41C, 41D are fixed to the terminal blocks 22B, 34B, 38A, the booster switching modules 22, the generator motor switching modules 33 and the swing motor switching modules 34 are electrically connected to one another.

Therefore, as compared with an instance where a long cable is used to bring the booster switching modules 22 and the generator motor switching modules 33 and the booster switching modules 22 and the swing motor switching modules 34 into electrical conduction, a length of a circuit for the electrical conduction can be significantly shortened. An inductance component in the DC line can thus be reduced, thereby suppressing resonance current caused by switching of the switching elements and, consequently, reducing heat generation.

### Other Component(s)

As shown in FIG. 4, a control circuit board 51 for collectively controlling the inverter 10 is provided in the upper cover 12 of the inverter 10. The control circuit board 51 is electrically connected to the gate substrates 21, 31, 32 through a cable (not shown). A metal shield 52 for noise suppression is provided below the control circuit board 51.

### Advantage(s) of Exemplary Embodiment(s)

The above-described exemplary embodiment provides the following advantages.

In the case 11 of the inverter 10, the third arrangement section 18 is in communication with the first and second arrangement sections 16, 17 through the opening 15A, and the smoothing capacitor unit 41 is disposed in the opening 15A. The smoothing capacitor unit 41 may thus be in the form of a single component including the integral first and second power storage portions 41A, 41B. Therefore, as compared with an instance where separate power storage portions (smoothing capacitors) are individually disposed on the upper and lower sides of the floor portion 15, the number of components can be reduced and, consequently, a work efficiency in, for instance, an assembly process can be improved.

Further, since the smoothing capacitor unit 41 is disposed to face both surfaces of the floor portion 15, the switching modules 22, 33, 34 can be reliably disposed close to the smoothing capacitor unit 41 to be connected thereto. Distance requirements between the switching modules 22, 33, 34 and the smoothing capacitor unit 41 can thus be satisfied and, consequently, generation of a surge can be suppressed.

Further, since the first power storage portion 41A and the second power storage portion 41B are integral with each other with a circuit length of a DC line therebetween being shortened, an inductance component in the DC line can be reduced to suppress resonance current caused by the inductance component.

In the cooling channel 15D, the plurality of first fins 15H project from the first planar portion 15B toward the second planar portion 15C, and the plurality of second fins 15I project from the second planar portion 15C toward the first planar portion 15B. Heat from the switching modules 22, 33, 34, the step-up transformer 24 and the smoothing capacitor unit 41 can thus be efficiently radiated to the cooling water and, consequently, a cooling effect can be improved.

Further, since the cooling channel 15D is defined by the groove-shaped portion 15E provided to the second planar portion 15C of the floor portion 15 and the cover plate 19 covering the groove-shaped portion 15E, the case 11 can be manufactured through a die-casting process with a higher accuracy than a gravity die-casting using a core.

It should be understood that the scope of the present invention is not limited to the above-described exemplary embodiment(s) but includes modifications and improvements as long as the modifications and improvements are compatible with the invention.

The smoothing capacitor is not necessarily a film capacitor but may be an electrolytic capacitor or the like.

Any ones of the above switching modules may be the first and second electronic components. For instance, when a step-up function is provided independently of an inverter, one of the first and second electronic components may be the generator motor switching modules and the other may be the swing motor switching modules, or the first and second electronic components may alternatively be inverted.

A cooling fin may be provided to at least one of the first and second planar portions, or may not be provided according to the invention.

The cover plate defining one of the planar portions is fixed to the other planar portion with a bolt, but may be fixed by welding or the like.

The cooling channel may be formed by gravity die-casting using a core. In this instance, a cover plate is not required. Further, even when a cover plate is required, almost all of an outer shell of the case may be manufactured through die-casting and the groove-shaped portion may be provided by machining or the like.

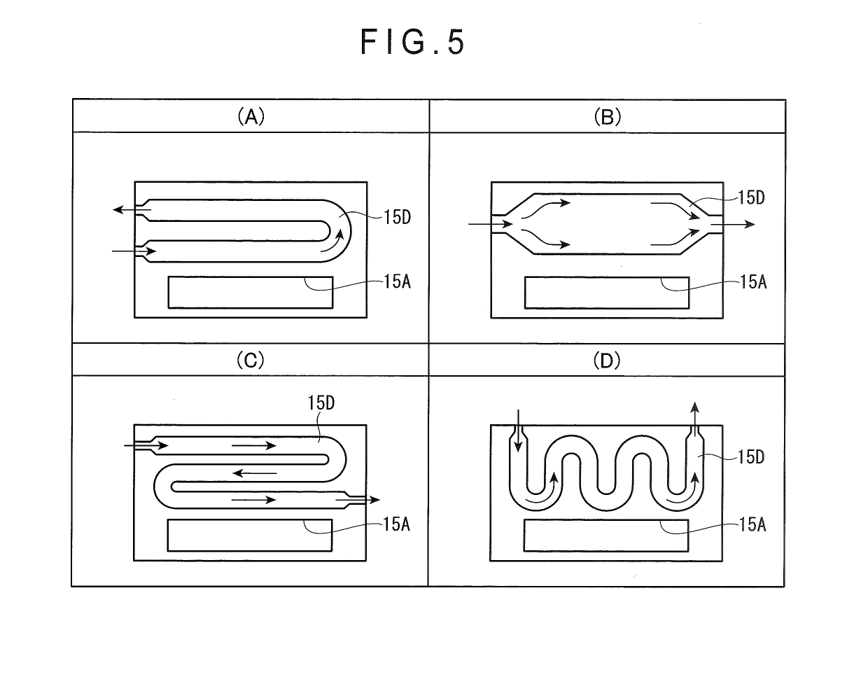

In the exemplary embodiment, the cooling channel is in a U-shape in a plan view as shown in FIG. 5 (an instance (A)), but may be in any shape such as an I-shape (an instance (B)), an N-shape (an instance (C)), a W-shape (an instance (D)) and an M-shape. Further, the inlet and outlet for the cooling water may be provided on a long side as in the instance (D). Further, a plurality of channels may be independently provided.

The coolant is not necessarily water but may alternatively be a non-freezing fluid or the like.

The electronic device is preferably a power conversion device, such as an inverter, including a switching element and a smoothing capacitor, but is not necessarily an inverter. In other words, any electronic device where first and second electronic components are respectively disposed in first and second arrangement sections defined across a cooling channel is acceptable.

The invention is applicable to an inverter for a hybrid construction machine other than a hydraulic excavator and to an inverter for a hybrid on-road truck or passenger vehicle.

### EXPLANATION OF CODE(S)

1 . . . hydraulic excavator (construction machine), 10 . . . inverter (electronic device), 11 . . . cooling case, 15 . . . floor portion, 15A . . . opening, 15B . . . first planar portion, 15C . . . second planar portion, 15D . . . cooling channel, 15H . . . first fin, 15I . . . second fin, 15J . . . long side, 16 . . . first arrangement section, 17 . . . second arrangement section, 18 . . . third arrangement section, 19 . . . cover plate, 22 . . . booster switching module (first electronic component), 33 . . . generator motor switching module (second electronic component), 34 . . . swing motor switching module (second electronic component), 41 . . . smoothing capacitor unit, 41A . . . first power storage portion, 41B . . . second power storage portion, 41C, 41D . . . terminal

1. A cooling case for an electronic device, the cooling case comprising:
a floor portion defining therein a cooling channel through which a coolant flows;
a first arrangement section where a first electronic component is disposed, the first arrangement section being defined in one of top and bottom surfaces of the floor portion;
a second arrangement section where a second electronic component is disposed, the second arrangement section being defined in the other of the top and bottom surfaces of the floor portion; and
a third arrangement section being in communication with the first arrangement section and the second arrangement section through an opening provided to the floor portion, wherein
a smoothing capacitor unit is disposed in the third arrangement section to face both of the top and bottom surfaces of the floor portion, the smoothing capacitor comprising a first power storage portion for a circuit provided to the first electronic component and a second power storage portion for a circuit provided to the second electronic component, the first power storage portion and the second power storage portion being integral with each other.

2. The cooling case for the electronic device according to claim 1, wherein
the floor portion comprises a first planar portion of the one of the top and bottom surfaces of the floor portion and a second planar portion of the other of the top and bottom surfaces of the floor portion,
the cooling channel is defined between the first planar portion and the second planar portion, and
at least one of a first fin and a second fin is provided in the cooling channel, the first fin projecting from the first planar portion toward the second planar portion, the second fin projecting from the second planar portion toward the first planar portion.

3. The cooling case for the electronic device according to claim 1, wherein
the floor portion comprises a first planar portion of the one of the top and bottom surfaces of the floor portion and a second planar portion of the other of the top and bottom surfaces of the floor portion,
the cooling channel is defined between the first planar portion and the second planar portion, and
at least one of the first planar portion and the second planar portion is in a form of a cover plate fixed to the other of the first planar portion and the second planar portion.

4. The cooling case for the electronic device according to claim 1, wherein
the cooling case is in a substantially rectangular shape having long sides and short sides in a plan view,
the opening is disposed beside one of the long sides, and
the cooling channel is disposed beside the other one of the long sides.

5. The cooling case for the electronic device according to claim 1, wherein
a plurality of terminals are provided to an exterior of the smoothing capacitor unit, and
a DC bus board is embedded in the smoothing capacitor unit so that the terminals are electrically conductive to one another through the DC bus board.

6. An electronic device comprising the cooling case according to claim 1.

7. A construction machine comprising the electronic device according to claim 6.
